(19) United States
(12) Patent Application Publication
(10) Pub. No.: US 2013/0154471 A1
(43) Pub. Date: Jun. 20, 2013

(54) OLED DEVICES

(71) Applicants: Donald Seton Farquhar, Niskayuna, NY (US); Michael Scott Herzog, Voorheesville, NY (US)

(72) Inventors: Donald Seton Farquhar, Niskayuna, NY (US); Michael Scott Herzog, Voorheesville, NY (US)

(73) Assignee: GENERAL ELECTRIC COMPANY, Schenectady, NY (US)

(21) Appl. No.: 13/326,912

(22) Filed: Dec. 15, 2011

(51) Int. Cl. H05B 33/04; H01J 9/00

(52) U.S. Cl. 313/504; 445/58

(57) ABSTRACT

An organic electroluminescent device includes a transparent substrate having a conductive coating, a plurality of electroactive layers, a cathode layer, and a protective wax layer. The wax layer may be disposed directly on an electrode, particularly a cathode. The wax layer alone protects the cathode and no getter material is required to exclude oxygen and/or moisture. An OLED lighting device capable of emitting light from front and back surfaces, wherein an adhesive layer, particularly a wax layer, is disposed between cathodes of two organic electroluminescent devices positioned back to back.

### BACKGROUND

By their design, organic light emitting diode (OLED) devices emit light over a large area. The uniformity of the light emission depends on several factors including the ability of the anode and cathode to conduct current and maintain a uniform electrical potential across the light emitting layers. In general, this may favor certain electrical layouts for busing current, and also limit the size of individual pixel elements.

Another aspect of light uniformity is the appearance of so-called dark spots. Not only do dark spots degrade the appearance of the light emitting device, they can also negatively impact its light output and efficiency. It has been observed that the appearance of dark spots can be divided into different categories. The first category is those that occur as a result of processing defects prior to applying a protective coating. The second category is those that form during the coating process. The third is those that form with time in the absence of exposure to environmental moisture and oxygen. The fourth category is those that form as a result to exposure to exposure to atmospheric gases and variations in temperature and humidity. There are many possible sources of dark spots, and the cathode, in particular, on the non-light emitting side of the device has been associated with appearance of dark spots.

The cathode material, for example, evaporated aluminum, may have defects (missing metal, delamination, contamination) that result from the production process. Moreover, the cathode may be damaged in subsequent processing operations or in environmental exposure of the finished device.

In an effort to protect the cathode many engineering polymers in the general category of adhesives and coatings have been proposed and evaluated as protective layers that directly contact the cathode. Because the cathode is subject to degradation by exposure to oxygen or moisture, the protective coatings themselves must be completely free of oxygen and moisture during their application. Further, because polymers generally exhibit some degree of permeability, an impermeable layer such as a metal foil must be provided in addition to the coating to address anticipated environmental conditions. The coating must provide good adhesion to the cathode yet not create self-stress to the device during normal variations in temperature. Further, the chemistry of the coating must be free from reactive components that could degrade the cathode. Thus it is difficult to find a low cost material that is well suited to protecting the cathode.

A relatively simple test of the compatibility of materials with the cathode is to observe the dark spot formation in the first three categories. Many engineering polymers, including thermoplastics, such as hot melt polymers, thermosets, such as urethanes and epoxies, and pressure sensitive adhesives, such as acrylics and silicones, tend to have a deleterious effect on the cathode over time. Degradation may be observed within hours, days or weeks, and can often be accelerated by temperature alone in the absence of moisture or oxygen bearing atmosphere. Whereas extraordinary steps can be performed to ensure that the materials are free from contamination such as ions, or moisture or oxygen, such steps are not desirable in producing a low cost device, and in themselves do not ensure that a material will suffice as a suitable protective coating.

Accordingly, there remains a need for materials that can protect the cathode and the device from damage due to chemical, mechanical and thermal stresses.

### BRIEF DESCRIPTION

It has been unexpectedly discovered that coating the cathode of an OLED device with a moisture resistant wax layer provides significant protection for the device from moisture and oxygen without causing damage.

Accordingly, in one aspect, the present invention relates to an organic electroluminescent device including a transparent substrate having a conductive coating, a plurality of electroactive layers, a cathode layer, and a protective wax layer. The wax layer may be disposed directly on an electrode, particularly a cathode. The wax layer alone protects the cathode and no getter material is required to exclude oxygen and/or moisture.

In another aspect, the present invention relates to an OLED lighting device capable of emitting light from front and back surfaces, wherein an adhesive layer, particularly a wax layer, is disposed between cathodes of two organic electroluminescent devices positioned back to back.

In yet another aspect, the present invention relates to processes for preparing such devices. The processes allowing the devices to be exposed to at least a small amount of air or moisture during fabrication, reducing cost and complexity.

### DRAWINGS

These and other features, aspects, and advantages of the present invention will become better understood when the following detailed description is read with reference to the accompanying drawings in which like characters represent like parts throughout the drawings, wherein:

FIG. 1 is a cross-sectional view of an OLED device according to the present invention, having a wax layer disposed on an electrode.

FIG. 2 is a cross-sectional view of an OLED device according to the present invention, having wax layer disposed on outer surfaces thereof.

FIG. 3 is a cross-sectional view of a back-to-back OLED device according to the present invention.

### DETAILED DESCRIPTION

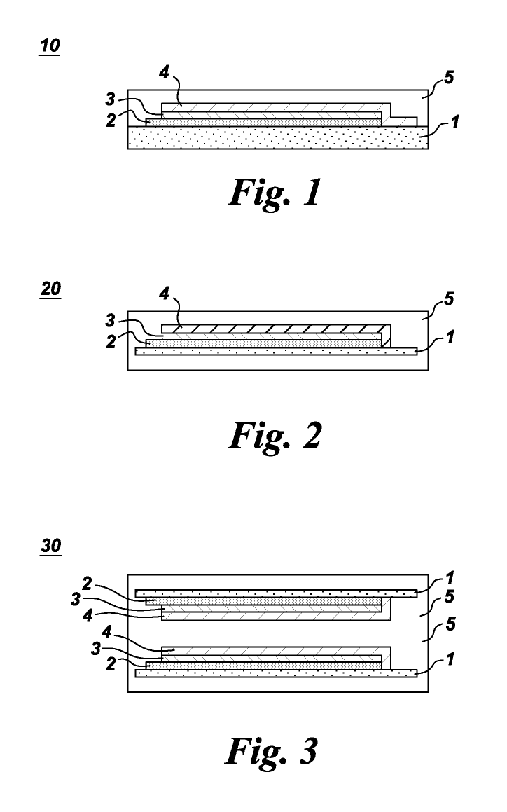

A first embodiment of the present invention is illustrated in FIG. 1. OLED device 10 is composed of substrate 1, anode 2, electroluminescent (EL) layers 3, cathode 4, and, disposed directly on the cathode, wax layer 5 comprising a wax composition. Substrate 1 is typically glass or plastic, but is not particularly limited. Plastic substrates may include an ultra-high barrier layer disposed on a polymer layer, for example, PET. Anode 2 is a transparent conductor, such as a transparent conductive oxide, for example, indium tin oxide, or a thin metal layer. The EL layers 3 include at least one organic light emitting layer, and may include hole injection layers, hole transport layers, electron injection layers, and electron transport layers. Suitable materials, structures, and configurations for the EL layers are well known in the art and are not described in detail here. Cathode 4 is a thin metal layer, typically aluminum, although not necessarily limited to any particular metal. Wax layer 5 is disposed directly on the cathode and also protects the cathode from thermal, mechanical and chemical damage.

### Example 1

An OLED device as shown in FIG. 1 was fabricated in a nitrogen glove box. After the cathode was deposited and the fabrication was completed, the device was heated to approximately 80° C. on a hot plate. Then a low melting (90° C.) wax was deposited on the cathode. Various means were used to disperse the wax in a thin uniform layer including brushing, doctor blading and roll coating. In each case, the performance of the device was monitored during the subsequent 72 hours in the glove box for the formation of dark spots. None were observed, indicating that the wax was compatible with the cathode. Subsequently the device was removed from the glove box and the performance of the device was monitored under standard room conditions (20° C., 50 r.h.) for the next 30 days. Less than 1% dark spot formation was observed during this period, confirming the compatibility of the wax with the device and also indicating that the wax was relatively impermeable to the environmental oxygen and moisture.

In subsequent trials, other waxes were evaluated both with melting points up to 120° C. and lower melting temperatures of 60° C. with similar results. These initial trials included paraffin waxes, but wax compositions suitable for use in wax layer 5 are not particularly limited, as long as they do not cause damage to surrounding layers. Suitable components of the composition include, but are not limited to, paraffin waxes having a melting point ranging from about 60° C. to about 120° C., particularly from about 80° C. to 100° C., more particularly 90° C. The melting temperature is above anticipated maximum operating conditions for example, about 60° C., and below temperatures and dwell times that may degrade the device, for example, 120° C. Also suitable are modified industrial waxes that have branched hydrocarbon chains, or have chemically inert additives such as such as silicones and/or fluorocarbons to modify chemical or mechanical properties, including melting point. Microcrystalline waxes may also be used. Various animal and plant waxes, for example, beeswax, may be suitable, depending on their mechanical properties, melting temperature and the application requirements.

In some embodiments, the wax composition is free of getter materials, as the wax alone possesses barrier properties and can protect the device from air and moisture when used alone as an outer layer of the device. In the context of the present invention, ‘getter’ means a chemical agent that reacts with water (moisture) and/or oxygen, for example, barium oxide, strontium oxide, calcium oxide, magnesium oxide, and other inorganic oxides. Getter materials and also adhesives that contain polar group, such as adhesion-promoting moieties or those resulting from crosslinking reactions, may be damaging to the cathode, and the device. The polar or reactive groups may attack the metal cathode. Particulate materials may pierce or otherwise mechanically damage the cathode. In addition, such groups may allow ingress of oxygen or moisture through the bulk material.

### Example 2

An OLED device substrate that had been fabricated on substrate composed of an ultra-high barrier (UHB) material was coated on a non-emissive side with a wax. Melted paraffin wax was applied to the cathode of the device in a glove box to produce a device having wax on the cathode surface and the UHB substrate as the opposite surface. The electrical contacts on the device to the cathode and anode were configured in such a way that they are accessible from the edge of the substrate. Various cathode configurations were included in the testing, including square and rectangular configurations. In general, there is no restriction on the shape or size of the cathode, or on the number of independently addressable cathode regions on a single substrate sharing a single anode.

In some embodiments, the positions of the cathode and anode are reversed and the wax layer is disposed on the anode. Wax layer 5 may be situated as an outermost layer, and protects the underlying electrode and the entire device. When wax layer is disposed on the emitting side of the device, for example, on the anode, or in a top emitting OLED panel wherein light emitted from the organic EL light-emitting layer is output through the cathode, or the wax is desirably transparent. This may be achieved when the wax itself is transparent, by suitably selecting the content of the wax, or by making the wax layer very thin.

### Example 3

An OLED device having a non-barrier plastic (PET) substrate was coated on both sides with a wax. Device 20 shown in FIG. 2 is composed of substrate 1, anode 2, EL layers 3, and cathode 4. Wax layer 5 is disposed on both cathode 4 and substrate 1. Melted paraffin wax was applied to the cathode and the substrate in a glove box to produce a device having wax on both outer surfaces. The means of wax coating include a two-step process of brushing melted wax on each side. Alternately, wax may be applied by a dipping process, followed by a doctor-blade process or other calendaring process. Various other means for depositing the wax may be used. One such possible means is to dissolve the wax in an organic solvent, such as xylene, and then to apply the wax, for example, by spraying, dipping or brushing, and then to dry the solvent. The electrical connections to the cathode and anode pass through the edge seal zone that is created around the perimeter of the device.

The average thickness of the wax was varied from as thin as 50 microns or less to as much as 500 microns or more. Even thinner layers are possible with solvent thinning of the wax. Within the entire range of thicknesses, the wax was compatible with the cathode, as indicated by lack of dark spot formation. A greater thickness may provide greater robustness in terms of abrasion resistance and possibly in terms of permeability.

In this third example, the wax is now protecting the cathode side and the emitting side substrate, thus the light path is through the wax. The wax has the effect of a diffuser and therefore can be selected for its thickness and optical properties to have the desired characteristic of masking any defects in the light emitting device.

The wax layers may be used as a very low cost package for devices 10 and 20, where the cathode, or the cathode and the substrate, that is, one or both outer surfaces, are protected only by a wax layer. Such devices may be suited for short lifetime applications, for example, in therapeutic medical health care applications where the device is only required to function for about a week or less. The device may be sealed in a hermetic foil bag until use, and then discarded after use. The wax layer(s) provide sufficient protection during storage and short term use of the device.

### Example 4

Two devices are positioned in a back-to-back relationship so that the two light emitting sides are facing outward. OLED lighting device 30 which is capable of emitting light from front and back surfaces is shown in FIG. 3. Lighting device 30 includes wax layer 5 disposed between cathodes 4 of two organic electroluminescent devices positioned back to back, and on both emitting surfaces of device 30. In some embodiments, the two cathodes may not completely isolated from each other by wax layer 5, and may be in electrical contact. Each of the individual organic electroluminescent devices includes substrate 1, which is composed of a non-barrier material, for example, plastic, anode 2, electroluminescent (EL) layers 3, and cathode 4. In other embodiments, layer 5 may be composed of a thermoplastic or thermoset adhesive material, especially in the area between the two cathodes.

In one variation, the electrical contacts from the anode and cathode of one device and the electrical contacts from a second device exit separately through the perimeter edge seal region. The two devices are bonded together by means of the wax layer on the cathode side, the wax layer also extending in some region beyond the cathode to form the edge seal region. In this variation, either device can be energized independently of the other. The bonding process was performed under two separate conditions, first, in the glove box and, second, after removal of the partially completed devices into ambient conditions.

In a second variation, silver-filled epoxy paste or some other electrically conductive adhesive was applied in a glove box to contact pads connected to the anodes and cathodes of two OLED devices that had been fabricated on a glass substrate and the devices were held on a hot plate. The cathodes of each were coated with a paraffin wax and the devices were stuck together cathode to cathode, and the device was taken off the hot plate to cool. The electrical connections between the anode and cathode contact pads were formed with electrically conductive adhesive, as well as the cathode to cathode bonding with paraffin in the same heating and cooling operation. The anodes of the two devices and the cathodes of the two devices were electrically connected, with cathodes of each of the two organic electroluminescent devices at a common potential.

Although the devices are conveniently joined in a two-dimensional back-to-back configuration, other shapes or structures are contemplated. For example, the devices may be assembled in the form of a cube, pyramid, sphere, geodesic dome or other figure, regular or irregular, with emitting surfaces on the outer surface of the figure, and the non-emitting surfaces isolated from the atmosphere.

### Example 5

Two light emitting devices built on a non-barrier plastic (PET) substrate were assembled as in Example 4 to produce a back-to-back device, and connected electrically. Then the device was dipped in melted paraffin wax in a shallow dish, and allowed to cool. In this example, the wax is now surrounding the entire package as shown in FIG. 3.

The stability of the cathode as characterized by the formation of dark spots was observed for 72 hours for all of the devices described in Examples 1-5, first in the controlled atmosphere (nitrogen glove box) in which they were fabricated. No degradation was observed, confirming the compatibility of the wax with the device. The devices were removed from the glove box, held under ambient conditions, and energized periodically to measure lifetime. All devices emitted light when energized after aging for 30 days or more, and dark spot formation was less than or equal to 1%.

OLED device 30 may be fabricated by bonding a first and second organic electroluminescent device in a back-to-back configuration. At least one of the first and second devices has an adhesive layer, particularly a wax layer, disposed on an outmost surface for bonding to the other device. In particular embodiments, the devices are bonded through a wax layer disposed directly on a cathode.

In another aspect, the present invention relates to a process for fabricating an organic electroluminescent device wherein a wax layer is coated directly on a cathode and the wax-coated device is exposed to at least a small amount of air or moisture. The wax coating may apply by known coating techniques, or the wax may be supplied as a film on a releasing substrate, and transferred from the releasing substrate to the surface of the device. In general, OLED fabrication steps, including deposition of the EL layers and cathode, are carried out under vacuum, and air and moisture are excluded from the atmosphere. In the process of the present invention, the cathode of the device is coated with wax, and then may be taken out of the hermetic environment. Subsequent steps, such as further packaging, tiling or wiring may be performed under a less stringent and less costly environment. The wax layer may be used as an intermediary layer underneath another adhesive and/or foil layer that provides an outer package.

The process may be used as part of a roll to roll fabrication process to provide temporary or permanent protection to the cathode to facilitate rolling up the OLED after deposition of the cathode for transport to another location for subsequent processes. Without the wax layer, the cathode may be damaged by contact and abrasion with subsequent layers.

1. An organic electroluminescent device having a wax layer disposed directly on an electrode, the wax layer comprising a wax composition free of getter material.

2. An organic electroluminescent device according to claim 1, wherein the wax layer is an outermost layer.

3. An organic electroluminescent device according to claim 1, wherein the electrode is a cathode.

4. An OLED lighting device capable of emitting light from front and back surfaces, the lighting device comprising an adhesive layer disposed between cathodes of two organic electroluminescent devices positioned back to back.

5. An OLED lighting device according to claim 4, wherein the adhesive layer comprises a wax.

6. An OLED lighting device according to claim 4, additionally comprising a transparent package encapsulating the two organic electroluminescent devices.

7. An OLED lighting device according to claim 6, wherein the transparent package comprises a wax composition.

8. An OLED lighting device according to claim 6, wherein the transparent package comprises a wax composition disposed directly on a non-barrier substrate.

9. An OLED lighting device according to claim 4, wherein cathodes of each of the two organic electroluminescent devices are at a common potential.

10. A process for packaging an organic electroluminescent device, said process comprising coating a wax layer directly on a cathode of the organic electroluminescent device and allowing exposure of the wax-coated device to at least a small amount of air or moisture.

11. A process according to claim 10, wherein the wax layer is coated on the cathode prior to removing the organic electroluminescent device from an atmosphere required for cathode deposition or preceding layer deposition steps.

12. A process according to claim 10, additionally comprising packaging the device after allowing exposure of the device to air or moisture.

13. A process for fabricating an organic electroluminescent device capable of emitting light from front and back surfaces, said process comprising bonding a first and second organic electroluminescent device in a back-to-back configuration.

14. A process according to claim 13, wherein at least one of the first and second devices comprises a wax layer.

15. A process according to claim 13, wherein the first and second devices each comprise a wax layer disposed directly on a cathode.

16. A process according to claim 13, additionally comprising depositing a wax layer on at least one of the front and back surfaces.

17. An organic electroluminescent device fabricated by the process of claim 10.

18. An organic electroluminescent device comprising a transparent substrate having a conductive coating, a plurality of electroactive layers, a cathode layer, and a protective wax layer.

19. An organic electroluminescent device according to claim 18, wherein the protective wax layer is an outermost layer.

20. An organic electroluminescent device according to claim 18, wherein the protective wax layer is disposed directly on a cathode.
